(19) United States
(12) Patent Application Publication
(10) Pub. No.: US 2026/0323946 A1
(43) Pub. Date: Oct. 15, 2026

(54) PILLAR STRUCTURE FOR MEMORY DEVICES

(71) Applicant: Micron Technology, Inc., Boise, ID (US)

(72) Inventors: Naveen KAUSHIK, Boise, ID (US); Pankaj SHARMA, Boise, ID (US); Haitao LIU, Boise, ID (US); Shuji TANAKA, KAMAKURA (JP)

(21) Appl. No.: 19/577,883

(22) Filed: Mar. 25, 2026

Related U.S. Application Data
(60) Provisional application No. 63/788,514, filed on Apr. 14, 2025.

(51) Int. Cl. H10B 43/35; H10B 43/27

(52) U.S. Cl. CPC H10B 43/35; H10B 43/27

(57) ABSTRACT

Implementations described herein relate to various structures, integrated assemblies, and memory devices. In some implementations, an integrated assembly may include a first semiconductive layer, a first dielectric layer disposed between the first semiconductive layer and a layer stack, and a pillar structure extending through the layer stack, through the first dielectric layer, and into the first semiconductive layer. A first portion of the pillar structure that extends through the layer stack may have a first diameter, and a second portion of the pillar structure that extends through the first dielectric layer may have a second diameter that is larger than the first diameter.

### CROSS-REFERENCE TO RELATED APPLICATION

This Patent Application claims priority to U.S. Provisional Patent Application No. 63/788,514, filed on Apr. 14, 2025, entitled “PILLAR STRUCTURE FOR MEMORY DEVICES,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a pillar structure for memory devices.

### BACKGROUND

Memory devices provide data storage for electronic systems. Flash memory is a type of non-volatile memory, meaning that the memory retains data in the absence of a power supply. As an example, an electronic device may use flash memory in a solid-state drive (SSD) for non-volatile storage of information, rather than a hard disk drive that uses magnetic disks for storage. NAND is a type of flash memory that has advantages over hard disk drives, such as lower erase times, lower write times, and less chip area per memory cell, which allows for more storage density and lower cost. The memory cells in NAND memory may be configured or formed in vertical stacks. This arrangement is sometimes called vertical NAND or three-dimensional (3D) NAND. 3D NAND arrangements enable a greater quantity of memory cells per chip surface area because of the vertical stacking of memory cells. 3D NAND arrangements also enable more options for the placement of cells to avoid interference and electron leakage, which can improve memory device performance. As the demand for storage capacity and performance increases, improvements in NAND architecture and improved methods for fabricating NAND memory are desirable.

### BRIEF DESCRIPTION OF THE DRAWINGS

FIG. 1 is a diagram illustrating an example of components included in a memory device.

FIG. 2 is a diagram illustrating an example of a NAND memory array described herein.

FIG. 3 is a diagram illustrating an example of a three-dimensional (3D) NAND memory array.

FIG. 4 includes a diagrammatic view related to an example memory device structure described herein.

FIGS. 5A and 5B are diagrammatic views of an example memory device structure. FIG. 5A is a top cross-sectional view along the line B-B of FIG. 5B, and FIG. 5B is a side cross-sectional view along the line A-A of FIG. 5A.

FIG. 6 is a flowchart of an example method of forming an integrated assembly or memory device having a pillar structure.

FIGS. 7A through 7I are diagrammatic views showing formation of the memory structure illustrated in FIGS. 5A and 5B.

### DETAILED DESCRIPTION

A semiconductor device may include a memory structure, such as a three-dimensional (3D) NAND memory block. The 3D NAND memory block often includes a string of memory cells that are vertically arranged.

To form the string of memory cells, which may correspond to select gate cells, a pillar structure may be formed through a stack of conductive layers alternating with dielectric layers, through a dielectric layer that is between the stack and a common source layer, and into a common source layer. A region in which a conductive layer (e.g., a word line) intersects with an outer layer of the pillar structure (e.g., a channel layer) may constitute a gate (e.g., a select gate, a control gate) of a select gate cell of the string of memory cells. The channel layer may correspond to a common channel region that is shared between the string of memory cells. The channel layer may couple the gates of the string of memory cells with the common source layer. A portion of the channel layer that is between the gate of a last memory cell in the string of memory cells and the common source layer may correspond to an ungated region of the channel layer.

A current that flows through the string of memory cells by way of the channel layer during access operations may be referred to as a “string current.” The structure of the channel layer, particularly within the ungated region of the channel layer, may impact the string current. In particular, the string current may be highly sensitive to defects or impurities in the ungated region (which may be referred to as “traps” in the ungated region) and the thickness of the ungated region.

The pillar structure may include a first portion that has a first, smaller diameter, and extends through the stack and the dielectric layer. Additionally, the pillar structure may include a second portion that has a second, larger diameter, and extends into the common source layer. Accordingly, the ungated region in the channel layer may include a kink (e.g., a curved or tapered section) that occurs between the dielectric layer and the common source layer, where the diameter of the pillar structure changes from the first to the second diameter. The kink in the channel layer may also increase the string current sensitivity.

Some implementations described herein provide an improved pillar structure for memory devices that decreases the string current sensitivity, particularly in relation to traps and the dimensions of the ungated region. In particular, techniques to form the memory device may be cause the kink in the channel layer to occur between the dielectric layer and the stack (e.g., instead of occurring between the dielectric layer and the common source layer). Accordingly, the kink in the channel layer may be closer to the last memory cell in the string of memory cells, and closer to the word line that corresponds to the last memory cell. By moving the kink in the channel layer closer to the word line, the shielding effect associated with the kink may be reduced, which may in turn reduce the string current sensitivity in the ungated region of the channel layer. Accordingly, implementations described herein relate to a pillar structure where the first portion of the pillar structure having the first (e.g., smaller) diameter extends through the stack, and the second portion of the pillar structure having the second (e.g., larger) diameter may extend through the dielectric layer and into the common source layer.

Techniques to form the memory device may include forming a cavity that extends through the stack and the dielectric layer to expose a surface of a plug structure that is formed in a semiconductive layer that corresponds to the common source layer. Then a portion of the first dielectric layer may be recessed to form a ring-shaped void that is defined by a bottom surface of the stack, a top surface of the plug structure, and a sidewall of the dielectric layer. After forming the ring-shaped void, the plug structure may be exhumed and the pillar may be formed. By recessing the portion of the dielectric layer prior to forming the pillar, the kink in the channel layer within the pillar may be closer to a word line (e.g., as opposed to a memory device that is formed without recessing the portion of the dielectric layer prior to forming the pillar). Accordingly, the manufacturing process of the memory device may be updated to include an additional etching step. In some implementations, the manufacturing process of the memory device may additionally be updated to adjust a deposition process associated with forming the dielectric layer, which may in turn enable the ring-shaped void to be formed without significantly impacting the stack.

In this way, the string current sensitivity of the memory device may be reduced, without significantly increasing a complexity of manufacturing the memory device. Reducing the string current sensitivity may increase a reliability and efficiency of the memory device. Additionally, refraining from increasing the complexity of forming or manufacturing the memory device may promote cost and time efficiency in the manufacturing process.

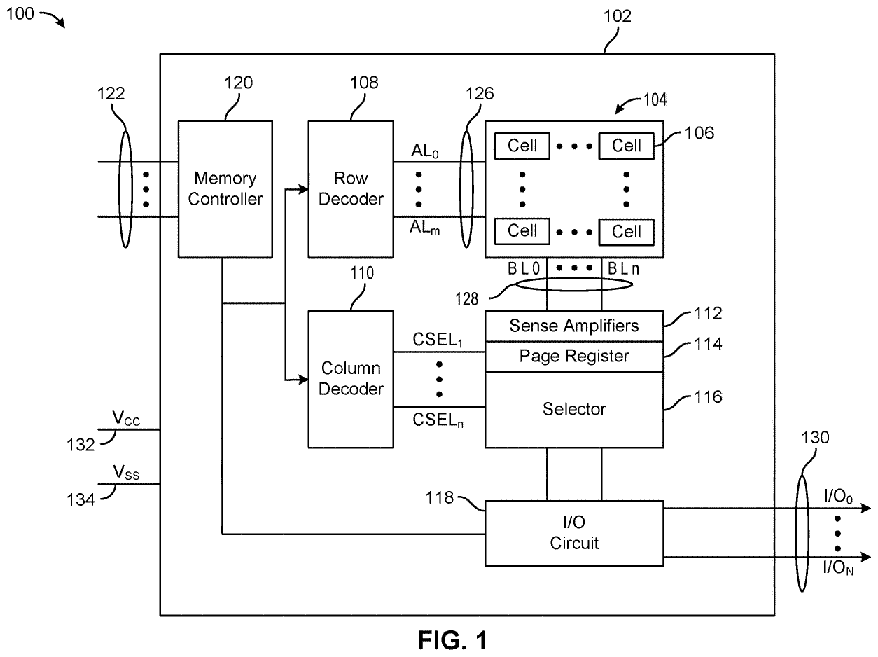

FIG. 1 is a diagram illustrating an example 100 of components included in a memory device 102 described herein. The memory device 102 may include a memory array 104 having multiple memory cells 106. The memory device 102 may include one or more components (e.g., circuits) to transmit signals to or perform memory operations on the memory array 104. For example, the memory device 102 may include a row decoder 108, a column decoder 110, one or more sense amplifiers 112, a page register 114, a selector 116, an input/output (I/O) circuit 118, and a memory controller 120.

The memory controller 120 may control memory operations of the memory device 102 according to one or more signals received by way of one or more control lines 122, such as one or more clock signals or control signals that indicate an operation (e.g., write, read, or erase) to be performed. Additionally, the one or more control lines 122 receive a command latch enable signal and/or an address latch enable signal (e.g., that indicates a type of bus cycle, such as a command, address, or data bus cycle that are being communicated via the I/O lines 130), a write enable signal (e.g., that controls a latching of data, commands, and/or addresses via the I/O lines 130), or other types of control signals. The memory controller 120 may determine one or more memory cells 106 upon which the operation is to be performed based on one or more signals received by way of, for example, one or more control lines 122 and one or more I/O lines 130. A host device external from the memory device 102 may control the values of the control signals on the control lines 122 or the indication of one or more address(es) on the I/O lines 130.

The memory device 102 may use access lines 126 (sometimes called word lines or row lines, and shown as AL0-ALm) and bit lines 128 (sometimes called digit lines, data lines, or column lines, and shown as BL0-BLn) to transfer data to or from one or more of the memory cells 106. For example, the row decoder 108 and the column decoder 110 may receive and decode the address signals from the memory controller 120 and may determine which of the memory cells 106 are to be accessed based on the address signals. In some cases, the memory controller 120 may indicate the one or more addresses to the row decoder 108 and the column decoder 110 via an address register. For example, the memory controller 120 may set the address register to a value that indicates one or more addresses associated with a command based on signal(s) received via the control lines 122 and via the I/O lines 130.

The row decoder 108 and the column decoder 110 may provide signals to those memory cells 106 by way of one or more access lines 126 and one or more bit lines 128, respectively.

For example, the column decoder 110 may receive and decode address signals into one or more column select signals (shown as CSEL1-CSELn). The selector 116 may receive the column select signals and may select data in the page register 114 that represents values of data to be read from or to be programmed into memory cells 106. The page register 114 may be configured to store data received from a host device before the data is programmed into relevant portions of the memory array 104, or the page register 114 may store data read from the memory array 104 before the data is transmitted to the host device. The sense amplifiers 112 may be configured to determine the values to be read from or written to the memory cells 106 using the bit lines 128. For example, in a selected string of memory cells 106, a sense amplifier 112 may read a logic level in a memory cell 106 in response to a read current flowing through the selected string to a bit line 128. The I/O circuit 118 may transfer values of data into or out of the memory device 102 (e.g., to or from a host device), such as into or out of the page register 114 or the memory array 104, using I/O lines 130 (shown as (I/O₀-I/Oₙ)).

The memory controller 120 may generate or receive positive and negative supply signals, such as a supply voltage (Vcc) 132 and a negative supply (Vss) 134 (e.g., a ground potential), from an external source or power supply (e.g., an internal battery, an external battery, or an AC-to-DC converter).

As indicated above, FIG. 1 is provided as an example. Other examples may differ from what is described with regard to FIG. 1.

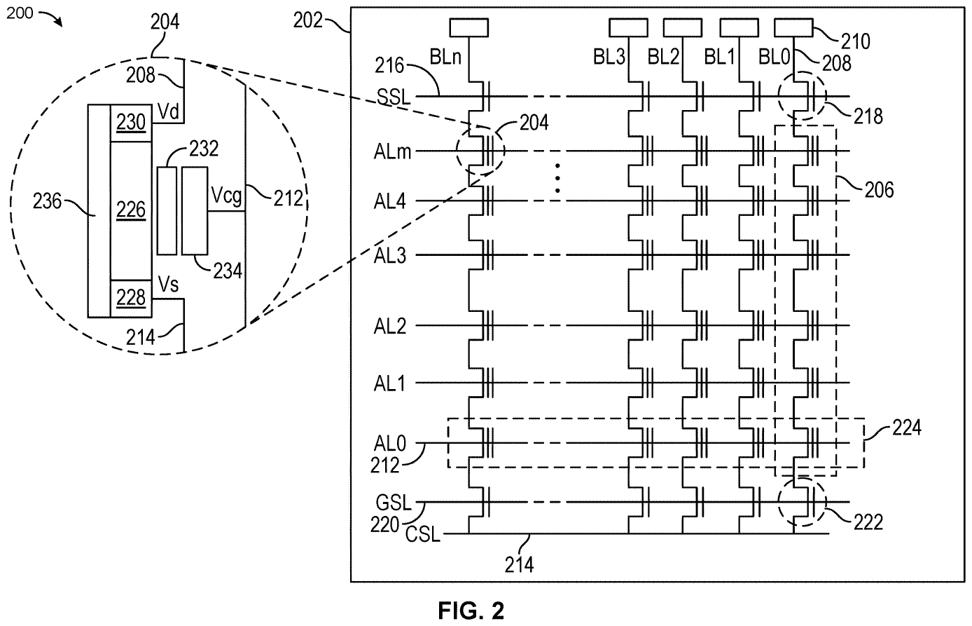

FIG. 2 is a diagram illustrating an example 200 of a NAND memory array 202 described herein. The NAND memory array 202 may correspond to the memory array 104 described above in connection with FIG. 1. The memory array 202 may be part of a three-dimensional stack of memory arrays, such as 3D NAND flash memory.

The memory array 202 includes multiple memory cells 204. A memory cell 204 may store an analog value, such as an electrical voltage or an electrical charge, that represents a data state (e.g., a digital value). The analog value and corresponding data state depend on a quantity of electrons trapped or present within a region of the memory cell 204 (e.g., in a charge trap), as described below.

A NAND string 206 (sometimes called a string) may include multiple memory cells 204 connected in series. A NAND string 206 is coupled to a bit line 208 (sometimes called a digit line or a column line, and shown as BL0-BLn). Data can be read from or written to the memory cells 204 of a NAND string 206 by way of a corresponding bit line 208 using one or more I/O components 210 (e.g., an I/O circuit, an I/O bus, a page register, or a sensing component, such as a sense amplifier). Memory cells 204 of different NAND strings 206 (e.g., one memory cell 204 per NAND string 206) may be coupled with one another by way of access lines 212 (sometimes called word lines or row lines, and shown as AL0-ALm) that select which row (or rows) of memory cells 204 is affected by a memory operation (e.g., a read operation or a write operation).

A NAND string 206 may be connected to a bit line 208 at one end and a common source line (CSL) 214 at the other end. A string select line (SSL) 216 may be used to control respective string select transistors 218. A string select transistor 218 selectively couples a NAND string 206 to a corresponding bit line 208. A ground select line (GSL) 220 may be used to control respective ground select transistors 222. A ground select transistor 222 selectively couples a NAND string 206 to the common source line 214.

A “page” of memory (or “a memory page”) may refer to a group of memory cells 204 connected to the same access line 212, as shown by reference number 224. In some implementations (e.g., for single-level cells), the memory cells 204 connected to an access line 212 may be associated with a single page of memory. In some implementations (e.g., for multi-level cells), the memory cells 204 connected to an access line 212 may be associated with multiple pages of memory, where each page represents one bit stored in each of the memory cells 204 (e.g., a lower page that represents a first bit stored in each memory cell 204 and an upper page that represents a second bit stored in each memory cell 204). In NAND memory, a page is the smallest physically addressable data unit for a write operation (sometimes called a program operation) and a read operation.

In some implementations, a memory cell 204 is a charge trapping memory cell. In this case, the memory cell 204 may include a channel 226, a source region 228, a drain region 230, a charge trapping region 232, and a control gate 234. The source region 228, the drain region 230, and the channel 226 may be on a substrate 236 (e.g., a semiconductor substrate). A memory device may store a data state in the memory cell 204 by charging the charge trapping region 232 to a particular voltage associated with the data state or to a voltage that is within a range of voltages associated with the data state. This results in a predefined amount of current flowing through the channel 226 (e.g., from the source region 228 to the drain region 230) when a specified read voltage is applied to the control gate 234 (e.g., by a corresponding access line 212 connected to the control gate 234). Although not shown, a tunnel oxide layer (or tunnel dielectric layer) may be interposed between the charge trapping region 232 and the channel 226, and a gate oxide layer (e.g., a gate dielectric layer) may be interposed between the charge trapping region 232 and the control gate 234. As shown, a drain voltage Vd may be supplied from a bit line 208, a control gate voltage Vcg may be supplied from an access line 212, and a source voltage Vs may be supplied by way of the common source line 214 (which, in some implementations, is a ground voltage).

To write or program the memory cell 204, Fowler-Nordheim tunneling may be used. For example, a strong positive voltage potential may be created between the control gate 234 and the channel 226 (e.g., by applying a large positive voltage to the control gate 234 by way of a corresponding access line 212) while current is flowing through the channel 226 (e.g., from the common source line 214 to the bit line 208, or vice versa). The strong positive voltage at the control gate 234 causes electrons within the channel 226 to tunnel through the tunnel oxide layer and be trapped in the charge trapping region 232. These negatively charged electrons then act as an electron barrier between the control gate 234 and the channel 226 that increases the threshold voltage of the memory cell 204. The threshold voltage is a voltage required at the control gate 234 to cause current (e.g., a threshold amount of current) to flow through the channel 226.

To read the memory cell 204, a read voltage may be applied to the control gate 234 (e.g., by way of a corresponding access line 212), and an I/O component 210 (e.g., a sense amplifier) may determine the data state of the memory cell 204 based on whether current passes through the memory cell 204 (e.g., the channel 226) due to the applied voltage. A pass voltage may be applied to all memory cells 204 (other than the memory cell 204 being read) in the same NAND string 206 as the memory cell 204 being read. For example, the pass voltage may be applied on each access line 212 other than the access line 212 of the memory cell 204 being read (e.g., where the read voltage is applied). The pass voltage is higher than the highest read voltage associated with any memory cell data states, so that all of the other memory cells 204 in the NAND string 206 conduct, and the I/O component 210, can detect a data state of the memory cell 204 being read by sensing current (or lack thereof) on a corresponding bit line 208. For example, in a single-level memory cell that stores one of two data states, the data state is a “1” if current is detected, and the data state is a “0” if current is not detected. In a multi-level memory cell that stores one of three or more data states, multiple read voltages are applied, over time, to the control gate 234 to distinguish between the three or more data states and determine a data state of the memory cell 204.

To erase the memory cell 204, a strong negative voltage potential may be created between the control gate 234 and the channel 226 (e.g., by applying a large negative voltage to the control gate 234 by way of a corresponding access line 212). The strong negative voltage at the control gate 234 causes trapped electrons in the charge trapping region 232 to tunnel back across the oxide layer from the charge trapping region 232 to the channel 226 and to flow between the common source line 214 and the bit line 208. This removes the electron barrier between the control gate 234 and the channel 226 and decreases the threshold voltage of the memory cell 204 (e.g., to an empty or erased state, which may represent a “1”). In NAND memory, a block is the smallest unit of memory that can be erased. A block of NAND memory includes multiple pages. Thus, an individual page of a block cannot be erased without erasing every other page of the block. In some implementations, a block may be divided into multiple sub-blocks. A sub-block is a portion of a block and may include a subset of pages of the block or a subset of memory cells of the block.

As indicated above, FIG. 2 is provided as an example. Other examples may differ from what is described with regard to FIG. 2.

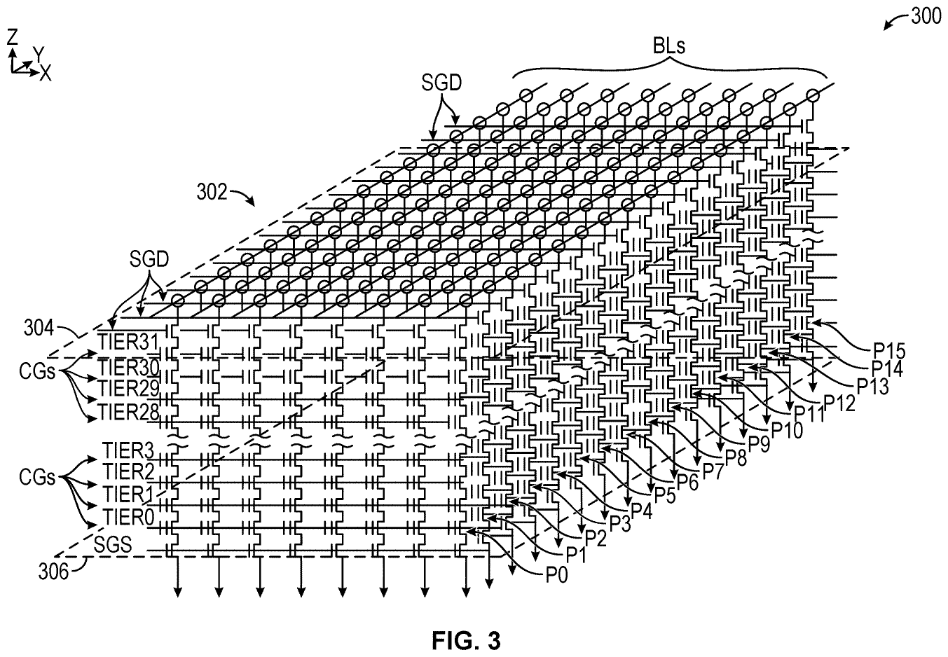

FIG. 3 is a diagram illustrating an example 300 of a 3D NAND memory array 302 described herein. The 3D NAND memory array 302 may correspond to the memory array 104 described above in connection with FIG. 1 or the NAND memory array 202 described above in connection with FIG. 2.

The 3D NAND memory array 302 includes multiple strings of memory cells. A string includes multiple tiers of charge storage transistors stacked in a first direction, shown as the Z direction. The charge storage transistors are stacked source-to-drain from a source-side select gate (SGS) to a drain-side select gate (SGD). In the example 300 of FIG. 3, each string includes 32 tiers (shown as TIER 0 through TIER 31). In other examples, each string of memory cells may include a different quantity of tiers (e.g., 8 tiers, 16 tiers, 64 tiers, or 128 tiers). The memory cells of a particular string may share a common channel region, such as one formed in a respective pillar of semiconductor material (e.g., polysilicon) about which the string of memory cells is formed.

Along a second direction, shown as the Y direction, multiple strings of memory cells are connected along bit lines (BLs). For example, a first group of strings is coupled to a first bit line extending in the second direction, a second group of strings is coupled to a second bit line extending in the second direction, and so on.

Along a third direction, shown as the X direction, memory cells in the same tier but in different strings are arranged in memory pages (shown as P0 through P15). For example, a group of memory cells in a tier may be coupled to the same access line to form a page (or multiple pages, in the example of multi-level cells). Within a page, each tier represents a row of memory cells, and each string of memory cells represents a column. A block of memory cells can include multiple pages, such as 128 pages or 384 pages.

Each memory cell includes a control gate (CG) coupled to an access line, as described above in connection with FIG. 2. The access line collectively couples the control gates of memory cells in a specific tier or a portion of a tier. A tier in the 3D NAND memory array 302 can be accessed or controlled using an access line. For example, the 3D NAND memory array 302 may include a first level of semiconductor material 304 (e.g., polysilicon) that couples the control gates of each memory cell in TIER31. Similar respective levels of metal or semiconductor material may couple the control gates for each respective tier. As further shown, the 3D NAND memory array 302 may include a second level of semiconductor material 306 that couples the SGSs of the array. The second level of semiconductor material 306 may correspond to a common source layer. Specific strings of memory cells in the 3D NAND memory array 302 can be accessed, selected, or controlled using a combination of bit lines and select gates, and specific memory cells at one or more tiers in the specific strings can be accessed, selected, or controlled using one or more access lines.

As indicated above, FIG. 3 is provided as an example. Other examples may differ from what is described with regard to FIG. 3. For example, the number of memory cells, strings, tiers, bit lines, access lines, or pages may be greater than or less than those shown in FIG. 3.

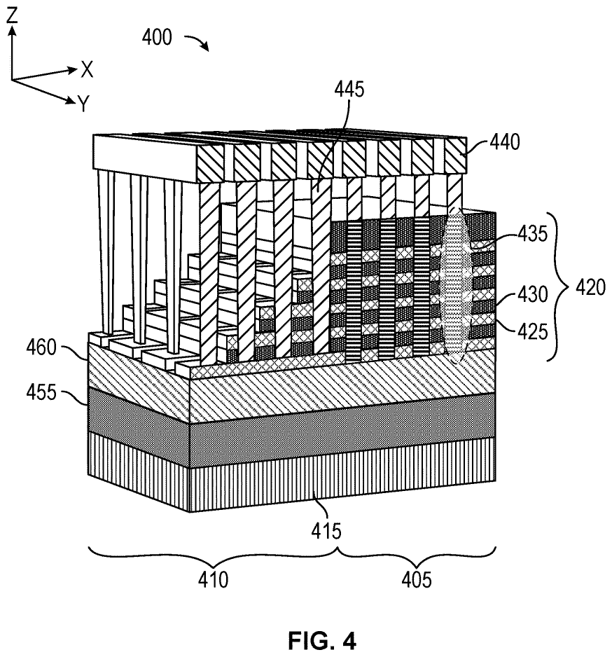

FIG. 4 includes a diagrammatic view related to an example memory device structure 400 described herein. In some embodiments, the memory device structure 400 corresponds to a structure of a three-dimensional (3D) NAND memory device.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

The memory device structure 400 includes a memory block region 405 and a staircase region 410. The memory block region 405 and the staircase region 410 each include portions of a substrate 415 and a tiered structure 420.

The memory device structure 400 may correspond to a structure of a 3D NAND memory device with a backside source configuration. That is, the memory device structure 400 may include a common source layer 455 that is disposed underneath (e.g., on the backside of) the memory block region 405 and the staircase region 410. The memory device structure 400 may include the dielectric layer 460 between the common source layer 455 and the tiered structure 420.

The substrate 415 may comprise, consist of, or consist essentially of semiconductive material. The semiconductive material may comprise, consist of, or consist essentially of silicon (e.g., polysilicon or polycrystalline silicon). Alternatively, and in some embodiments, the substrate 415 comprises, consists of, or consists essentially of silicon carbide, a type III-V semiconductor material (e.g., a semiconductor material that includes a group III element and a group IV element such as gallium nitride), a semiconductor-on-insulator (SOI) substrate, or a semiconductor layer of an SOI substrate, among other examples.

The common source layer 455 may comprise, consist of, or consist essentially of semiconductive material doped with impurities that enable the common source layer 455 to be a conductive layer under an applied voltage. The semiconductive material may comprise, consist of, or consist essentially of silicon (e.g., polysilicon or polycrystalline silicon). Additionally, or alternatively, the common source layer 455 consists of, or consists essentially of polycrystalline silicon, silicon carbide, a III-V semiconductor material, or another suitable semiconductive material, among other examples. In some embodiments, the impurities include an n-type dopant such as phosphorous or another suitable n-type dopant, among other examples.

The dielectric layer 460 may be an electrical insulator and may comprise, consist of, or consist essentially of insulative material. As used herein, an insulative material may comprise, consist of, or consist essentially of an oxide (e.g., silicon oxide, aluminum oxide, or another suitable oxide material) or a nitride (e.g., silicon nitride aluminum nitride, or another suitable nitride material), among other examples.

The tiered structure 420 may include conductive layers 425 that are interspersed (e.g., alternate vertically) with dielectric layers 430. Each of the conductive layers 425 may be an electrical conductor and may comprise, consist of, or consist essentially of conductive material. As used herein, a conductive material may comprise, consist of, or consist essentially of a metal (e.g., titanium, tungsten, cobalt, nickel, platinum, or ruthenium), a metal composition (e.g., a metal silicide, a metal carbide, or a metal nitride, such as titanium nitride or titanium silicon nitride), or a conductively-doped semiconductor material (e.g., conductively-doped silicon, conductively-doped germanium, or conductively-doped gallium arsenide), among other examples. Furthermore, one or more of the conductive layers 425 may correspond to a word line layer of the memory device structure 400.

Each of the dielectric layers 430 may be an electrical insulator and may comprise, consist of, or consist essentially of insulative material. As used herein, an insulative material may comprise, consist of, or consist essentially of an oxide (e.g., silicon oxide, aluminum oxide, or another suitable oxide material) or a nitride (e.g., silicon nitride aluminum nitride, or another suitable nitride material), among other examples. Furthermore, the dielectric layers 430 may correspond to an inter-gate dielectric layer of the memory device structure 400.

Within the memory block region 405, one or more pillar structures 435 may penetrate through the tiered structure 420. The pillar structures 435 may each include an annular distribution (e.g., one or more layered rings) of semiconductive materials or insulative materials that form a channel or a storage cell of the memory device structure 400.

The memory device structure 400 may further include one or more conductive structures 440 that are above the tiered structure 420 and that span the memory block region 405 or the staircase region 410. The conductive structures 440 may each include one or more conductive materials. Furthermore, each of the conductive structures 440 may form a digit line of the memory device structure 400 (e.g., a digit line). The memory device structure 400 may further include one or more contact structures 445 that are vertically-oriented and connect the conductive structures 440 with the pillar structures 435 or conductive layers 425. The contact structures 445 may each include one or more conductive materials as described above.

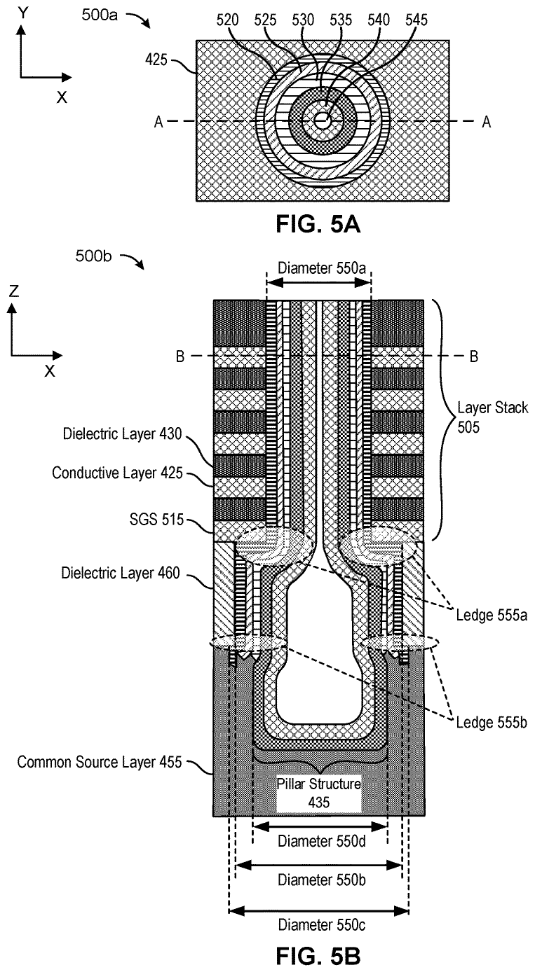

FIGS. 5A and 5B include diagrammatic views 500 related to an example memory device structure described herein. The memory device structure may be part of an integrated assembly, such as a memory array, a portion of a memory array, or a memory device that includes the memory array and one or more other components (e.g., sense amplifiers, a row decoder, a column decoder, a row address buffer, a column address buffer, one or more data buffers, one or more clocks, one or more counters, and/or a memory controller). In some embodiments, the memory device structure corresponds to a structure within a 3D NAND memory device. For example, the memory device structure may illustrate another example of a pillar structure 435, as described with reference to FIG. 4.

FIGS. 5A and 5B include diagrammatic views 500 related to an example memory device structure described herein. The memory device structure may be part of an integrated assembly, such as a memory array, a portion of a memory array, or a memory device that includes the memory array and one or more other components (e.g., sense amplifiers, a row decoder, a column decoder, a row address buffer, a column address buffer, one or more data buffers, one or more clocks, one or more counters, and/or a memory controller). In some embodiments, the memory device structure corresponds to a structure within a 3D NAND memory device.

The diagrammatic views 500 illustrate an example pillar structure 435, described with reference to FIG. 4. Additionally, the diagrammatic views 500 illustrate the conductive layers 425, the dielectric layers 430, the common source layer 455, and the dielectric layer 460 described with reference to FIG. 4.

FIG. 5A illustrates a first cross-sectional view of the pillar structure 435 taken along the z-axis and FIG. 5B illustrates a second cross-sectional view of the pillar structure 435 taken along the y-axis. In particular, a cross section (e.g., an elevation view cross section in the x-z plane) taken along the A-A section line illustrated in FIG. 5A may correspond to the diagrammatic view 500b of the memory device structure illustrated in FIG. 5B. Additionally, a cross section (e.g., a top view cross section in the x-y plane) taken along the B-B section line illustrated in FIG. 5B may correspond to the diagrammatic view 500a of the memory device structure illustrated in FIG. 5A.

The memory device structure may include the common source layer 455, a dielectric layer 460, and a layer stack 505. The common source layer 455 (e.g., a semiconductive layer) may comprise, consist of, or consist essentially of a semiconductive material doped with impurities that enable the common source layer 455 to be a conductive layer under an applied voltage (e.g., under an applied threshold voltage, or Vt). The semiconductive material may comprise, consist of, or consist essentially of silicon (e.g., a polysilicon material such as polycrystalline silicon or polysilicon). Additionally, or alternatively, the common source layer 455 may consist of, or consist essentially of polycrystalline silicon, silicon carbide, a III-V semiconductor material, or another suitable semiconductive material, among other examples. In some embodiments, the impurities include a n-type dopant such as phosphorous, arsenic, or another suitable n-type dopant, among other examples. In some other embodiments, the impurities include a p-type dopant such as boron or another suitable p-type dopant, among other examples.

The dielectric layer 460 may extend between the common source layer 455 and the layer stack 505. That is, a bottom surface of the dielectric layer 460 may contact a top surface of the common source layer 455, and a top surface of the dielectric layer 460 may contact a bottom surface of the layer stack 505. The dielectric layer 460 may extend between 40 to 100 nm along the z-axis. The dielectric layer 460 may be an electrical insulator and may comprise, consist of, or consist essentially of insulative material. The dielectric layer 460 may comprise, consist of, or consist essentially of a carbon-doped nitride material or an oxide material (e.g., a silicon oxide). If the dielectric layer 460 comprises, consists of, or consists essentially of the carbon-doped nitride material, carbon dopant concentration may be between 10% and 30%.

The layer stack 505 may include alternating dielectric layers 430 and conductive layers 425. The conductive layers 425 within the layer stack 505 may correspond to word line layers or word lines. In some implementations, the conductive layer 425 at the bottom of the layer stack 505 (e.g., the conductive layer 425 that is in contact with the dielectric layer 460) may correspond to an SGS 515. In some other implementations, the conductive layer 425 at the bottom of the layer stack 505 may correspond to a word line layer or a word line.

The pillar structure 435 may include a set of layers that form a cell stack (e.g., including a dielectric layer 520, a dielectric layer 525, and a dielectric layer 530), a channel layer 535, and a dielectric layer 540. In particular, the set of layers that form the cell stack may correspond to an outer layer or sheath of the pillar structure 435 and may be disposed around the channel layer 535. That is, the set of layers that form the cell stack may be horizontally interposed between the sidewalls of the layer stack 505 and the channel layer 535. In particular, the dielectric layer 520 may be horizontally interposed between the sidewalls of the layer stack 505 and the dielectric layer 525. The channel layer 535 may extend between the set of layers that form the cell stack and the dielectric layer 540. That is, the channel layer 535 may be horizontally interposed between the cell stack and the dielectric layer 540 and may contact the dielectric layer 530 and the dielectric layer 540. In some implementations, the pillar structure 435 may include a cavity (e.g., corresponding to a space 545). If the pillar structure 435 does include the cavity corresponding to the space 545, a height of the cavity within the pillar structure 435 (e.g., within the portion of the pillar structure 435 that extends into the common source layer 455) may be between 120 nm and 400 nm (e.g., in the z-direction). The cavity may be defined by the dielectric layer 540.

In some other implementations, the dielectric layer 540 may fill the cavity such that the space 545 within the pillar structure 435 is omitted. Here, the dielectric layer 540 may correspond to a dielectric cylinder that extends through a center of the pillar structure 435.

As indicated above, the cell stack may include the first dielectric layer 520, the second dielectric layer 525, and the third dielectric layer 530. The first dielectric layer 520 may also be referred to as a “bottom oxide layer,” and may be an electrical insulator that comprises, consists of, or consists essentially of insulative material. The insulative material may comprise, consist of, or consist essentially of an oxide (e.g., silicon oxide, aluminum oxide, or another suitable oxide material). The second dielectric layer 525 may include memory material that is capable of charge trapping. For example, the second dielectric layer 525 may include a nitride material (e.g., silicon nitride aluminum nitride, or another suitable nitride material). The third dielectric layer 530 may also be referred to as a “blocking oxide,” or “top oxide,” and may be an electrical insulator that comprises, consists of, or consists essentially of insulative material. The insulative material may comprise, consist of, or consist essentially of an oxide (e.g., silicon oxide, aluminum oxide, or another suitable oxide material).

The channel layer 535 (e.g., a semiconductive layer) may comprise, consist of, or consist essentially of a semiconductive material doped with impurities that enable the channel layer 535 to be a conductive layer under an applied voltage (e.g., under an applied threshold voltage, or Vt). The semiconductive material may comprise, consist of, or consist essentially of silicon (e.g., a polysilicon material such as polycrystalline silicon or polysilicon). Additionally, or alternatively, the channel layer 535 may consist of, or consist essentially of polycrystalline silicon, silicon carbide, a III-V semiconductor material, or another suitable semiconductive material, among other examples. In some embodiments, the impurities include a p-type dopant such as boron or another suitable p-type dopant, among other examples. In some embodiments, the impurities include an n-type dopant such as phosphorous and/or arsenic, among other examples.

The channel layer 535 and the common source layer 455 may both comprise, consist of, or consist essentially of a semiconductive material doped with impurities. Additionally, the channel layer 535 and the common source layer 455 may include different types of dopants. That is, if the channel layer 535 includes a p-type dopant, the common source layer 455 may include an n-type dopant. Additionally, if the channel layer 535 includes an n-type dopant, the common source layer 455 may include a p-type dopant.

The dielectric layer 540 (e.g., a dielectric fill) may comprise, consist, or consist essentially of insulative material. The insulative material may comprise, consist of, or consist essentially of an oxide (e.g., silicon oxide, aluminum oxide, or another suitable oxide material) or a nitride (e.g., silicon nitride aluminum nitride, or another suitable nitride material), among other examples.

The pillar structure 435 may include a first portion that has a first diameter 550a, a second portion that has a second diameter 550b, and a third portion that has a third diameter 550c. The first portion of the pillar structure 435 may extend through the layer stack 505 and may have the first diameter 550a. The second portion of the pillar structure 435 may extend through the dielectric layer 460 and may have the second diameter 550b, and the third portion of the pillar may extend into the common source layer 455 and may have the third diameter 550c. The first diameter 550a may be smaller than the second diameter 550b and the third diameter 550c. For example, the first diameter 550a may be between 10 and 15 nm smaller than the second diameter 550b or the third diameter 550c. Additionally, the second diameter 550b may be smaller than the third diameter 550c (e.g., as illustrated in FIG. 5B). In some other implementations, the second diameter 550b and the third diameter 550c may be the same size (e.g., not illustrated in FIG. 5B).

The pillar structure 435 may include a ledge 555a where the diameter of the pillar structure 435 changes from first diameter 550a to the second diameter 550b. The ledge 555a may be between 10 and 15 nm wide, and may correspond to a difference between the first diameter 550a and the second diameter 550b. The ledge 555a may be in contact with the layer stack 505. That is, a top surface of the ledge 555a may contact a bottom surface of the layer stack 505. In particular, the top surface of the ledge 555a may contact the bottom surface of the lowest conductive layer 425 within the layer stack 505. In some implementations, the lowest conductive layer 425 may correspond to the SGS 515. In some other implementations, the lowest conductive layer 425 within the layer stack 505 may correspond to a word line.

In some implementations, the pillar structure 435 may include a ledge 555b where the diameter of the pillar structure 435 changes from the second diameter 550b to the third diameter 550c. In particular, if the third diameter 550c is larger than the second diameter 550b (e.g., and not the same as the second diameter 550b), the pillar structure 435 may include the ledge 555b that corresponds to the difference between the second diameter 550b and the third diameter 550c. The ledge 555b may be less than 15 nm wide. The ledge 555b may be in contact with the dielectric layer 460. That is, a top surface of the ledge 555b may contact a bottom surface of the dielectric layer 460.

In some implementations, the pillar structure 435 may include a fourth portion that has a fourth diameter 550d. The fourth portion of the pillar structure 435 may extend (e.g., along the z-axis) into the common source layer 455. The fourth portion of the pillar structure 435 may correspond to a portion of the pillar structure 435 that does not include the set of layers that form the cell stack (e.g., the first dielectric layer 520, the second dielectric layer 525, and the third dielectric layer 530). That is, the fourth portion of the pillar structure 435 may include the channel layer 535, the dielectric layer 540 and, optionally, the space 545 (e.g., if the pillar includes the space 545).

Accordingly, the pillar structure 435 may include an overhanging structure where the diameter of the pillar structure 435 changes from the third diameter 550c to the fourth diameter 550d. The overhanging structure of the pillar structure 435 may contact the common source layer 455. As a result, a portion of the first dielectric layer 520, a portion of the second dielectric layer 525, and a portion of the third dielectric layer 530 may be in contact with the common source layer 455. The common source layer 455 may also contact the channel layer 535 within the fourth portion of the pillar structure 435. That is, the channel layer 535 may define an outer layer of the pillar structure 435 within the fourth portion of the pillar structure 435 and may be in contact with the common source layer 455.

In some implementations (e.g., not illustrated in FIG. 5B), the sidewalls of the pillar structure 435 may be sloped outward. For example, the second portion of the pillar structure 435 (e.g., that is surrounded by the dielectric layer 460) may have slanted sidewalls. Here, instead of the pillar structure 435 including the ledge 555b, the pillar structure 435 may include sloped sidewalls that gradually transition the pillar structure 435 from the second diameter 550b to the third diameter 550c.

The ledges 555 of the pillar structure 435 may result in a kink of the channel layer 535 (e.g., where the channel layer 535 curves). The kink in the channel layer 535 may introduce a shielding effect to the channel corresponding to the channel layer 535, which may in turn cause the string current through the channel to be sensitive to defects or impurities, particularly in the portion of the channel layer 535 that is within the dielectric layer 460 (which may correspond to the ungated region).

The memory device structure may be associated with a decreased string current sensitivity, as compared to an example memory device structure where the kink of the channel layer 535 is farther from a word line (or from the SGS 515) and closer to the common source layer 455. In particular, the kink of the channel layer 535 being close to a word line (or to the SGS 515) may decrease the shielding effect to the channel that results from the kink. Accordingly, the channel layer 535 may be less sensitive to defects or impurities as compared to a channel layer 535 that has a large kink farther from a word line (or from the SGS 515).

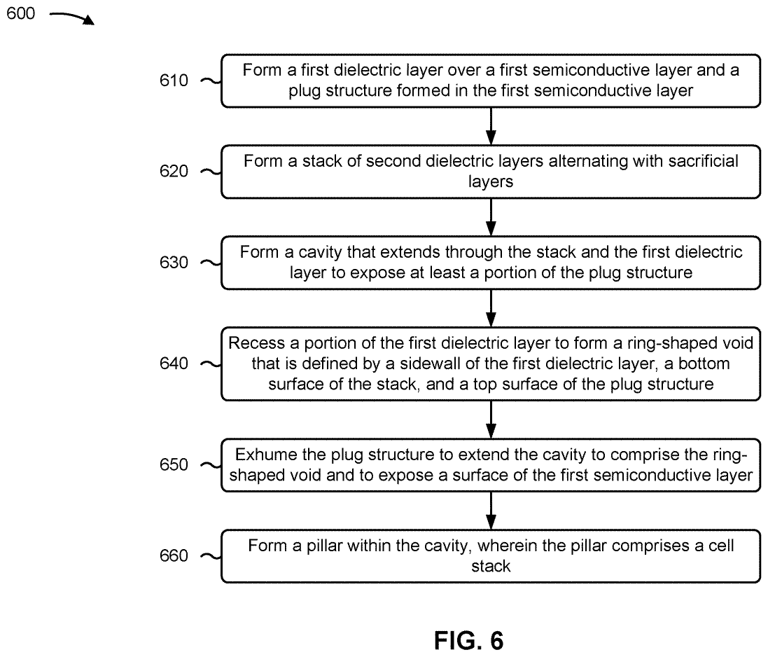

FIG. 6 is a flowchart of an example method 600 of forming an integrated assembly or memory device having the pillar structure described herein (e.g., as illustrated in FIGS. 5A and 5B). In some implementations, one or more process blocks of FIG. 6 may be performed by various semiconductor manufacturing equipment.

As shown in FIG. 6, the method 600 may include forming a first dielectric layer over a first semiconductive layer and a plug structure formed in the first semiconductive layer (block 610). As further shown in FIG. 6, the method 600 may include forming a stack of second dielectric layers alternating with sacrificial layers (block 620). As further shown in FIG. 6, the method 600 may include forming a cavity that extends through the stack and the first dielectric layer to expose at least a portion of the plug structure (block 630). As further shown in FIG. 6, the method 600 may include recessing a portion of the first dielectric layer to form a ring-shaped void that is defined by a sidewall of the first dielectric layer, a bottom surface of the stack, and a top surface of the plug structure (block 640). As further shown in FIG. 6, the method 600 may include exhuming the plug structure to extend the cavity to comprise the ring-shaped void and to expose a surface of the first semiconductive layer (block 650). As further shown in FIG. 6, the method 600 may include forming a pillar within the cavity, wherein the pillar comprises a cell stack (block 660).

The method 600 may include additional aspects, such as any single aspect or any combination of aspects described below and/or in connection with one or more other methods described elsewhere herein.

In a first aspect, recessing the portion of the first dielectric layer comprises applying an etchant that is selective to the first dielectric layer relative to the second dielectric layers.

In a second aspect, alone or in combination with the first aspect, the first dielectric layer comprises a carbon-doped nitride material and the second dielectric layers comprise a silicon oxide material, and the etchant selectively etches the carbon-doped nitride material relative to the silicon oxide material.

In a third aspect, alone or in combination with the first aspect, the first dielectric layer corresponds to a bilayer oxide layer that comprises a first oxide material and a second oxide material, the second dielectric layers comprise the second oxide material, and recessing the portion of the first dielectric layer comprises selectively etching the first oxide material relative to the second oxide material.

In a fourth aspect, alone or in combination with the third aspect, forming the bilayer oxide layer comprises depositing the first oxide material using a first deposition technique and depositing the second oxide material using a second deposition technique that is different from the first deposition technique, a first density of the first oxide material is lower than a second density of the second oxide material based at least in part on the first deposition technique and the second deposition technique being different, and the etchant selectively etches the first oxide material relative to the second oxide material based at least in part on the first density of the first oxide material being lower than the second density of the second oxide material.

In a fifth aspect, alone or in combination with one or more of the first through fourth aspects, the method 600 includes removing, after forming the pillar, the sacrificial layers to form a plurality of voids between the second dielectric layers, and depositing a conductive material within the plurality of voids.

Although FIG. 6 shows example blocks of the method 600, in some implementations, the method 600 may include additional blocks, fewer blocks, different blocks, or differently arranged blocks than those depicted in FIG. 6. In some implementations, the method 600 may include forming the memory structure illustrated in FIGS. 5A and 5B, an integrated assembly that includes the memory structure illustrated in FIGS. 5A and 5B, any part described herein of the memory structure illustrated in FIGS. 5A and 5B, and/or any part described herein of an integrated assembly that includes the memory structure illustrated in FIGS. 5A and 5B.

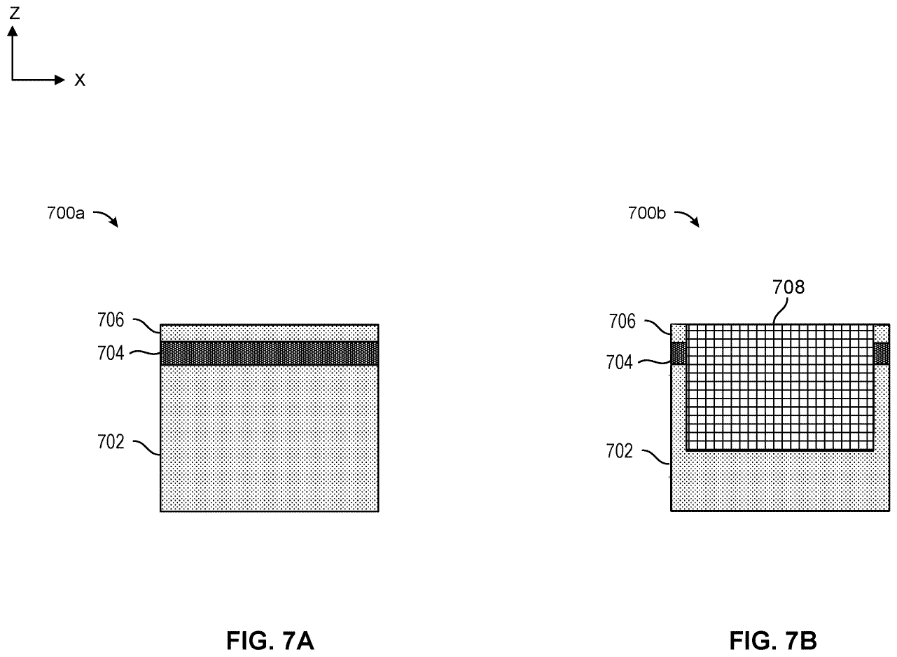

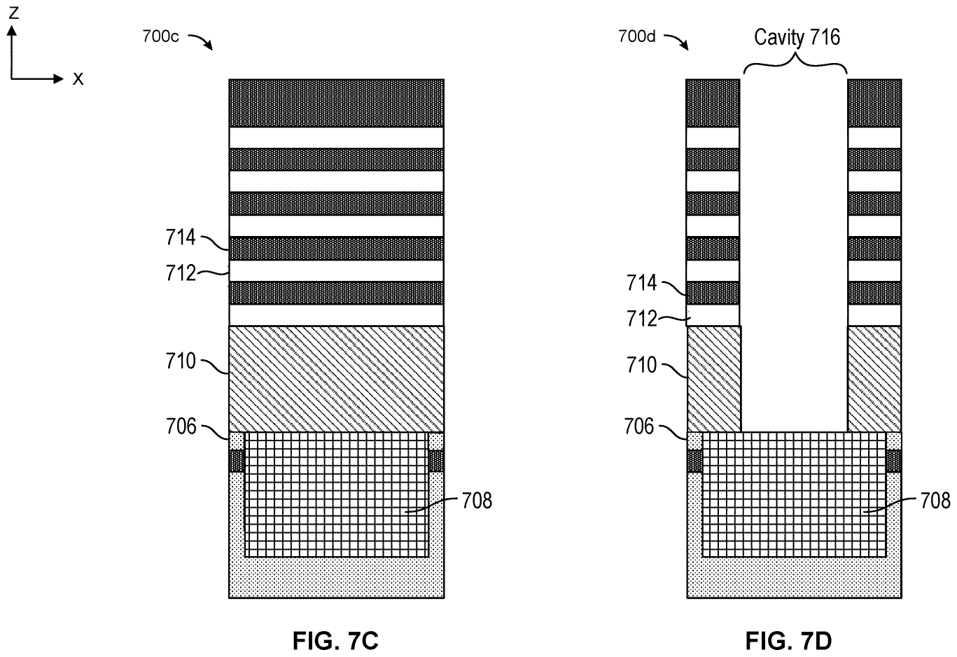

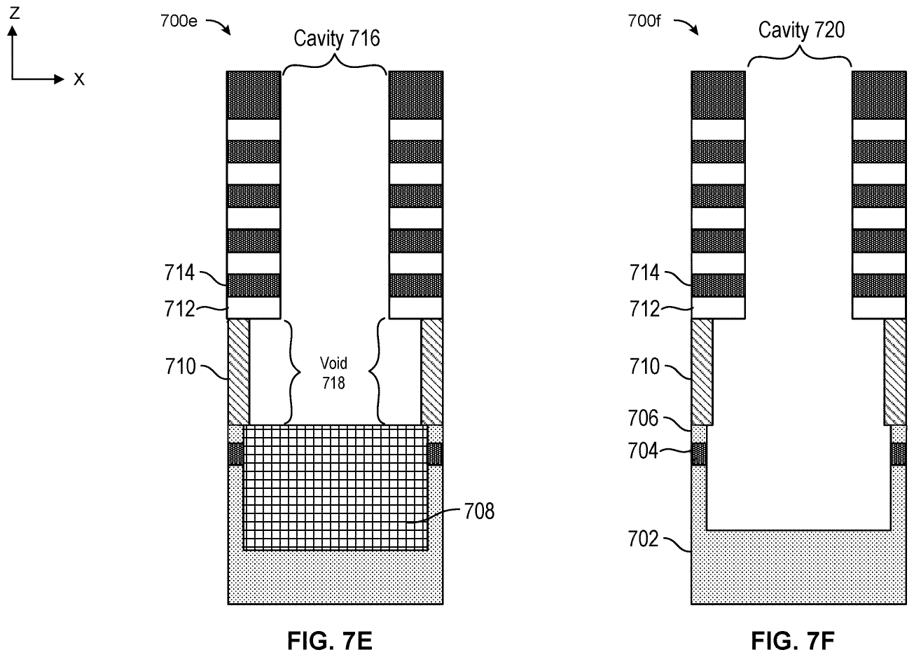

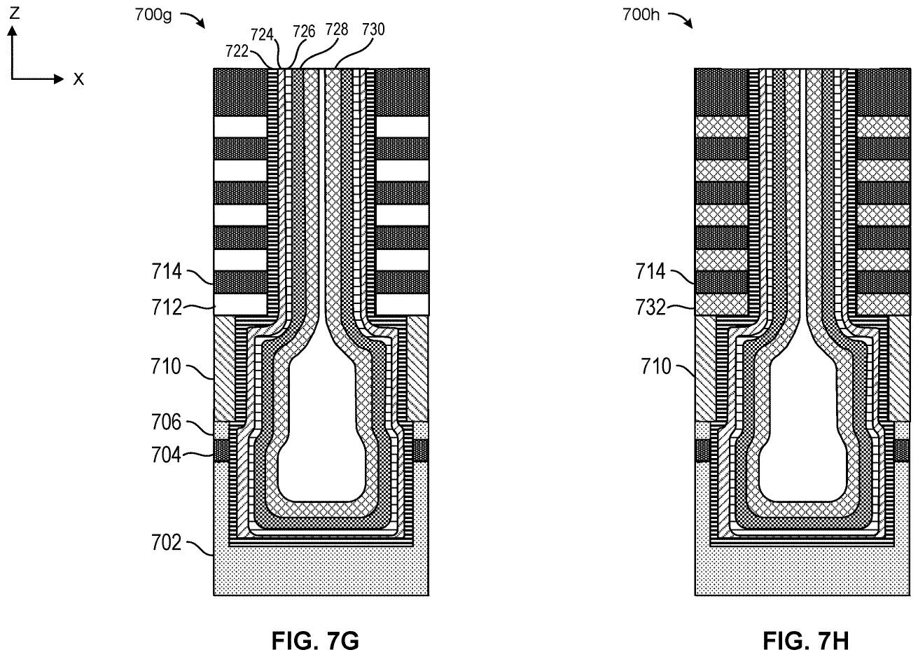

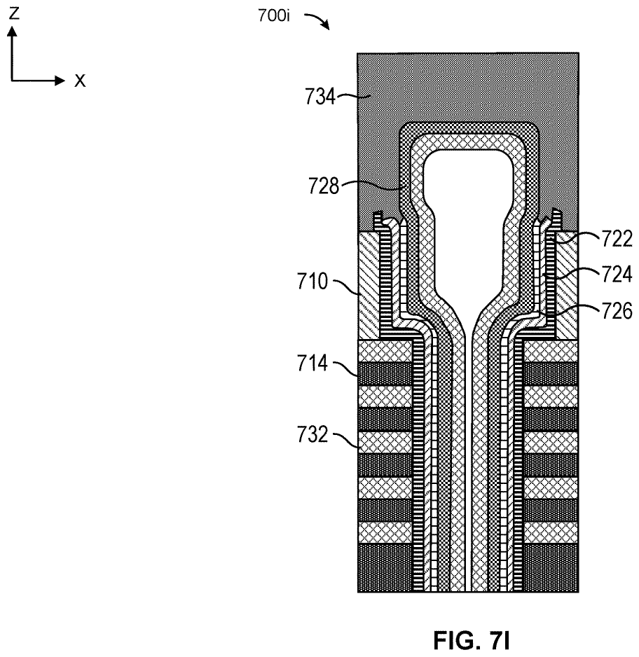

FIGS. 7A through 7I are diagrammatic views showing formation of the memory structure illustrated in FIGS. 5A and 5B at example process stages of an example process of forming the memory structure illustrated in FIGS. 5A and 5B. In particular, FIGS. 7A through 7I may illustrate intermediate structures 700 that are formed during the formation of the memory structure illustrated in FIGS. 5A and 5B. In some implementations, the example process described below in connection with FIGS. 7A through 7I may correspond to the method 600 and/or one or more blocks of the method 600. However, the process described below is an example, and other example processes may be used to form the memory structure illustrated in FIGS. 5A and 5B, an integrated assembly that includes the memory structure illustrated in FIGS. 5A and 5B, and/or one or more parts of the memory structure illustrated in FIGS. 5A and 5B and/or the integrated assembly.

As shown in FIG. 7A, the intermediate structure 700a may be formed. In particular, the process may include forming (e.g., depositing or growing) a semiconductive layer 702, a dielectric layer 704 over the semiconductive layer 702, and a semiconductive layer 702 over the dielectric layer 704.

The semiconductive layer 702 and the semiconductive layer 706 may include a semiconductive material and may correspond to a substrate. The semiconductive layer 702 and the semiconductive layer 706 may comprise, consist of, or consist essentially of silicon (e.g., polysilicon or polycrystalline silicon). Alternatively, and in some embodiments, the semiconductive layer 702 and the semiconductive layer 706 comprise, consist of, or consist essentially of silicon carbide, a type III-V semiconductor material (e.g., a semiconductor material that includes a group III element and a group IV element such as gallium nitride), a semiconductor-on-insulator (SOI) substrate, or a semiconductor layer of an SOI substrate, among other examples.

The dielectric layer 704 may comprise, consist of, or consist essentially of silicon oxide or another suitable dielectric material, among other examples.

As shown in FIG. 7B, the intermediate structure 700b may be formed. In particular, the process may include forming a plug structure 708. For example, the process may include removing (e.g., etching) a portion of the semiconductive layer 702, a portion of the dielectric layer 704, and a portion of the semiconductive layer 706 to form a cavity. The cavity may be defined by sidewalls of the semiconductive layer 706, the dielectric layer 704, and the semiconductive layer 702. The cavity may expose a surface of the semiconductive layer 702. In some implementations, one or more masks may be used to form the cavity. For example, one or more masks may be deposited and/or patterned on the semiconductive layer 706 prior to removing material to form the cavity.

Then the process may include depositing an etch stop material within the cavity to form the plug structure 708. The etch stop material may comprise, consist of, or consist essentially of aluminum, a silicon nitride, a polysilicon, tungsten, silicon oxide, or any other etch stop material that prevents further etching subsequently in the process.

As shown in FIG. 7C, the intermediate structure 700c may be formed. In particular, the process may include forming a dielectric layer 710 over the semiconductive layer 706 and the plug structure 708. The process may additionally include forming a stack of alternating sacrificial layers 712 and dielectric layers 714.

To form the dielectric layer 710, the process may include forming (e.g., depositing or growing) a dielectric material on a top surface of the intermediate structure 700b (e.g., corresponding to an exposed surface of the plug structure, and two top exposed surfaces of the semiconductive layer 706). The dielectric layer 710 may form the dielectric layer 460 and may comprise, consist of, or consist essentially of one or more of the materials described above in connection with the dielectric layer 460. In one example, the dielectric layer 710 may comprise, consist of, or consist essentially of a carbon-doped nitride material or an oxide material (e.g., a silicon oxide).

If the dielectric layer 710 comprises, consists of, or consists essentially of the carbon-doped nitride material, carbon dopant concentration may be between 10% and 30%. The carbon doping of the carbon-doped nitride material may cause the dielectric layer 710 to be selective to the sacrificial layers 712 (e.g., such that an etchant may be used to selectively etch the dielectric layer 710 relative to the sacrificial layers 712).

If the dielectric layer 710 comprises, consists of, or consists essentially of the oxide material, forming the dielectric layer 710 may include forming a bilayer oxide layer that corresponds to the dielectric layer 710. In some implementations, the bilayer oxide layer may include a first layer of an oxide material and a second layer of the oxide material. For example, the first layer of the bilayer oxide material may be formed using a first deposition technique and the second layer of the bilayer oxide material may be formed using a second deposition technique, which may enable the dielectric layer 710 to include the bilayer oxide layer.

In one example, the bilayer oxide material may include a first oxide layer (e.g., that comprises, consists of, or consists essentially of an oxide material, such as silicon oxide) that is formed using a tier deposition technique (e.g., similar to a technique used to form the alternating sacrificial layers 712 and dielectric layers 714) and a second oxide layer (e.g., that comprises, consists of, or consists essentially of an oxide material, such as silicon oxide) that is formed using a high aspect ratio process (HARP) deposition technique. For example, the first oxide layer may be 125 angstroms thick and the second oxide layer may be 375 angstroms thick.

The temperature during the HARP deposition of the second oxide layer may be adjusted to impact a density of the second oxide layer. For example, the temperature during the HARP deposition may be decreased (e.g., to a temperature that is less than 375 °C), which may in turn decrease a resulting density of the second oxide layer (e.g., as compared to an oxide layer that is formed using a tier deposition technique and as compared to an oxide layer that is formed using a HARP deposition with a higher temperature). As a result of the decreased density, the second oxide layer within the dielectric layer 710 may have a higher wafer etch rate (e.g., may be removed more effectively by an etchant) as compared to oxide layers with higher densities.

To form the stack of the sacrificial layers 712 alternating with the dielectric layers 714, the process may include forming (e.g., depositing or growing) a dielectric material on a top surface of the dielectric layer 710. The dielectric layers 714 may form the dielectric layers 430 and may comprise, consist of, or consist essentially of one or more of the materials described above in connection with the dielectric layers 430. The process may additionally include forming (e.g., depositing or growing) a sacrificial material over the top surfaces of the dielectric layers 714. The sacrificial layers 712 may comprise, consist of, or consist essentially of a tier nitride material (e.g., silicon nitride). The sacrificial layers 712 may comprise, consist of, or consist essentially of a material that is selective to the material of the dielectric layers 714 (e.g., that can be selectively etched while the dielectric layers 714 are not etched).

As shown in FIG. 7D, the intermediate structure 700d may be formed. In particular, the process may include forming the cavity 716. To form the cavity 716, the process may include removing (e.g., etching) a portion of the intermediate structure 700c to form the cavity 716. In some embodiments, one or more masks may be used to form the cavity 716. For example, one or more masks may be deposited or patterned on the top dielectric layer 714 (e.g., the top dielectric layer 714 along the z-axis of the intermediate structure 700c) prior to removing material to form the cavity 716.

The cavity 716 may extend through the stack of sacrificial layers 712 alternating with the dielectric layers 714, extend through the dielectric layer 710, and expose a top surface (e.g., along the z-axis) of the plug structure 708). In particular, an etchant that is used to form the cavity 716 may not be capable of etching the plug structure 708. Accordingly, the plug structure 708 may act as an etch-stop during the formation of the cavity 716. The sidewalls of the cavity 716 correspond to exposed sidewalls of the alternating sacrificial layers 712 and dielectric layers 714 and exposed sidewalls of the dielectric layer 710.

As shown in FIG. 7E, the intermediate structure 700e may be formed. In particular, the process may include forming a ring-shaped void 718. To form the ring-shaped void 718, the process may include recessing (e.g., etching) a portion of the dielectric layer 710. To form the ring-shaped void 718, the process may include applying an etchant to the intermediate structure 700d that is selective to the dielectric layer 710 relative to the sacrificial layers 712, the dielectric layers 714, and the plug structure 708. That is, the etchant may etch the material within the dielectric layer 710 faster than the materials within the sacrificial layers 712, the dielectric layers 714, or the plug structure 708.

If the dielectric layer 710 includes a carbon-doped nitride material, to form the ring-shaped void 718, the process may include applying an etchant that is selective to the carbon-doped nitride material over the silicon oxide material within the dielectric layers 714. Additionally, if the dielectric layer 710 corresponds to a bilayer oxide layer, to form the ring-shaped void 718, the process may include applying an etchant that is selective to the second oxide layer relative to the first oxide layer, the silicon oxide material within the dielectric layers 714, and the sacrificial layers 712. Here, the etchant may be selective to the second oxide layer based on the second oxide layer having a lower density (e.g., and a higher wafer etch rate) as compared to the first oxide layer and the silicon oxide material within the dielectric layers 714. In some implementations, the etchant may include hydrofluoric acid.

The ring-shaped void 718 may be defined by a bottom surface of the bottom sacrificial layer 712, a top surface of the plug structure 708, and a sidewall of the dielectric layer 710. The ring-shaped void 718 may extend the sidewalls of the cavity 716 between 5 to 25 nm outwards (e.g., along the x-axis). While the intermediate structure 700e illustrates the ring-shaped void 718 as including substantially vertical sidewalls, in some other implementations, the ring-shaped void 718 may include sidewalls that slope outwards. For example, the top of the ring-shaped void 718 (e.g., that is defined by the bottom surface of the bottom sacrificial layer 712) may extend the cavity 716 out a smaller distance than the bottom of the ring-shaped void 718 (e.g., that is defined by the top of the plug structure 708).

As shown in FIG. 7F, the intermediate structure 700f may be formed. In particular, the process may include exhuming (e.g., removing, etching) the plug structure 708 to form the cavity 720. The cavity 720 may extend through the stack of sacrificial layers 712 alternating with the dielectric layers 714, extend through the dielectric layer 710, extend through the semiconductive layer 706, extend through the dielectric layer 704, and extend into the semiconductive layer 702.

A first portion of the cavity 720 that extends through the stack of sacrificial layers 712 alternating with the dielectric layers 714 may have a first diameter, and a second portion of the cavity 720 that extends through the dielectric layer 710 may have a second, larger diameter. The cavity 720 having the second, larger, diameter may be based at least in part on forming the ring-shaped void 718 prior to forming the cavity 720. A third portion of the cavity 720 that extends through the semiconductive layer 706, through the dielectric layer 704, and into the semiconductive layer 702 may have a third diameter. In some implementations, the third diameter may be the same as the second diameter. For example, if the ring-shaped void 718 extends outward from the cavity 716 to the edge of the plug structure 708 (e.g., to a boundary between the plug structure 708 and the semiconductive layer 706), then the third diameter may be the same as the second diameter. In some other implementations, the third diameter may be larger than the second diameter. For example, if the ring-shaped void 718 extends outward from the cavity 716 farther than the edge of the plug structure 708 (e.g., farther than the boundary between the plug structure 708 and the semiconductive layer 706), then the third diameter may larger than the second diameter.

As shown in FIG. 7G, the intermediate structure 700g may be formed. In particular, the process may include forming a pillar within the cavity 720 of the intermediate structure 700h. In particular, the process may include forming (e.g., depositing or growing) the dielectric layer 722 over or along a contour of the cavity 720. The dielectric layer 722 may form the dielectric layer 520 and may comprise, consist of, or consist essentially of one or more of the materials described above in connection with the dielectric layer 520.

The process may additionally include forming (e.g., depositing or growing) the dielectric layer 724 over or along a contour of a remaining portion of the cavity 720 that exists after the dielectric layer 722 is formed. The dielectric layer 724 may form the dielectric layer 525 and may comprise, consist of, or consist essentially of one or more of the materials described above in connection with the dielectric layer 525.

The process may additionally include forming (e.g., depositing or growing) the dielectric layer 726 over or along a contour of a remaining portion of the cavity 720 that exists after the dielectric layer 724 is formed. The dielectric layer 726 may form the dielectric layer 530 and may comprise, consist of, or consist essentially of one or more of the materials described above in connection with the dielectric layer 530. The dielectric layers 722, 724, and 726 may correspond to a cell stack, as described with reference to FIGS. 5A and 5B.

The process may additionally include forming (e.g., depositing or growing) the channel layer 728 over or along a contour of a remaining portion of the cavity 720 that exists after the dielectric layer 726 is formed. The channel layer 728 may form the channel layer 535 and may comprise, consist of, or consist essentially of one or more of the materials described above in connection with the channel layer 535.

The process may additionally include forming (e.g., depositing or growing) the dielectric layer 730 over or along a contour of a remaining portion of the cavity 720 that exists after the channel layer 728 is formed. The dielectric layer 730 may form the dielectric layer 540 and may comprise, consist of, or consist essentially of one or more of the materials described above in connection with the dielectric layer 540.

In some implementations, after forming the dielectric layer 730 there may be a space or void within the pillar. That is, the pillar structure may be hollow. In some other implementations (e.g., not illustrated in FIG. 7G), the process may include filling the remaining portion of the cavity 720 that exists after the channel layer 728 is formed with a dielectric material. Here, the dielectric layer 730 may correspond to a cylindrical core that extends vertically within the pillar structure, and the space or void within the pillar may be omitted.

As shown in FIG. 7H, the intermediate structure 700h may be formed. To form the intermediate structure 700h, the process may include forming the conductive layers 732. To form the conductive layers 732, the sacrificial layers 712 may be exhumed from the intermediate structure 700g to form a set of voids between the dielectric layers 714. Then a conductive material is deposited within the set of voids (e.g., to fill the set of voids) and form the conductive layers 732. The conductive layers 732 may form the conductive layers 425 and may comprise, consist of, or consist essentially of one or more of the materials described above in connection with the conductive layers 425.

The conductive layers 732 alternating with the dielectric layers 714 may correspond to the layer stack 505 described above in connection with FIGS. 5A and 5B.

As shown in FIG. 7I, the intermediate structure 700i may be formed. In some cases, the intermediate structure 700i may correspond to the memory device structure described and illustrated in connection with FIGS. 5A and 5B.

To form the intermediate structure 700i, the process may include forming the semiconductive layer 734, which may correspond to the common source layer 455.

To form the semiconductive layer 734, the process may include flipping the intermediate structure 700h (e.g., with respect to the z-axis) upside-down to expose a bottom surface of the semiconductive layer 702. The process may then include removing (e.g., etching, exhuming) the semiconductive material 702, the dielectric material 704, and the semiconductive material 706 from the intermediate structure 700h.

The process may additionally include cutting (e.g., etching, removing) a portion of the cell stack layers that extend beyond the dielectric layer 710 (e.g., that are disposed above the dielectric layer 710 along the z-axis). In particular, the process may include removing a portion of the dielectric layer 722, a portion of the dielectric layer 724, and a portion of the dielectric layer 726. Accordingly, the cell stack layers within the intermediate structure 700i may extend (e.g., along the z-axis) through the dielectric layer 710 and through the conductive layers 732 alternating with the dielectric layers 714. Additionally, the cell stack layers within the intermediate structure 700i may not extend through the semiconductive layer 734.

After removing the portion of the cell stack layers, the process may include forming the semiconductive layer 734. For example, the process may include depositing a semiconductive material over the dielectric layer 710, the channel layer 728, and the cell stack layers to form the semiconductive layer 734. Accordingly, the semiconductive layer 734 may be in contact with the channel layer 728, and a portion of the dielectric layer 710 and the cell stack layers. The semiconductive layer 734 may include a semiconductive material that comprises, consists of, or consists essentially of a semiconductive material doped with impurities that enable the semiconductive layer 734 to be a conductive layer under an applied voltage.

As indicated above, the process steps described in connection with FIGS. 7A through 7I are provided as examples. Other examples may differ from what is described with respect to FIGS. 7A through 7I. The structure shown in FIG. 7I may be equivalent to the structure 5A and 5B described elsewhere herein. In process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

In some implementations, an integrated assembly includes a first semiconductive layer; a first dielectric layer disposed between the first semiconductive layer and a layer stack; and the layer stack disposed above the first dielectric layer, the layer stack comprising alternating dielectric layers and conductive layers; and a pillar structure extending through the layer stack, through the first dielectric layer, and into the first semiconductive layer, wherein a first portion of the pillar structure that extends through the layer stack has a first diameter, wherein a second portion of the pillar structure that extends through the first dielectric layer has a second diameter that is larger than the first diameter, and wherein the pillar structure comprises: a second semiconductive layer, and a second dielectric layer around the second semiconductive layer and comprising memory material.

In some implementations, an apparatus includes a common source layer; a source-side select gate layer disposed over the common source layer, wherein a first dielectric layer extends vertically between the common source layer and the source-side select gate layer; and a pillar comprising a string of memory cells and extending vertically through the source-side select gate layer and at least a portion of the common source layer, wherein a first portion of the pillar that extends through the source-side select gate layer has a first diameter, and wherein a second portion of the pillar that extends through the first dielectric layer has a second diameter that is larger than the first diameter.

In some implementations, a method includes forming a first dielectric layer over a first semiconductive layer and a plug structure formed in the first semiconductive layer; forming a stack of second dielectric layers alternating with sacrificial layers; forming a cavity that extends through the stack and the first dielectric layer to expose at least a portion of the plug structure; recessing a portion of the first dielectric layer to form a ring-shaped void that is defined by a sidewall of the first dielectric layer, a bottom surface of the stack, and a top surface of the plug structure; exhuming the plug structure to extend the cavity to comprise the ring-shaped void and to expose a surface of the first semiconductive layer; and forming a pillar within the cavity, wherein the pillar comprises a cell stack.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” All ranges described herein are inclusive of numbers at the ends of those ranges, unless specifically indicated otherwise. As used herein, the term “formed” may, depending on the context, refer to a state or a position of a first feature relative to a second feature, and does not imply any specific method or sequence of formation.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b +b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An integrated assembly, comprising:
a first semiconductive layer;
a first dielectric layer disposed between the first semiconductive layer and a layer stack; and
the layer stack disposed above the first dielectric layer, the layer stack comprising alternating dielectric layers and conductive layers; and
a pillar structure extending through the layer stack, through the first dielectric layer, and into the first semiconductive layer,
wherein a first portion of the pillar structure that extends through the layer stack has a first diameter,
wherein a second portion of the pillar structure that extends through the first dielectric layer has a second diameter that is larger than the first diameter, and wherein the pillar structure comprises:
a second semiconductive layer, and
a second dielectric layer around the second semiconductive layer and comprising memory material.

2. The integrated assembly of claim 1, wherein a third portion of the pillar structure that extends into the first semiconductive layer has a third diameter that is larger than the second diameter.

3. The integrated assembly of claim 1, wherein the first dielectric layer comprises carbon-doped nitride material.

4. The integrated assembly of claim 3, wherein the dielectric layers in the layer stack comprise an oxide material that is different from the carbon-doped nitride material.

5. The integrated assembly of claim 1, wherein the first dielectric layer comprises an oxide material.

6. The integrated assembly of claim 5, wherein the dielectric layers in the layer stack comprise the oxide material.

7. The integrated assembly of claim 1, wherein:
the first semiconductive layer comprises a first type of dopant; and
the second semiconductive layer comprises a second, opposite type of dopant.

8. The integrated assembly of claim 1, wherein the pillar structure further comprises:
a third dielectric layer around the second dielectric layer;
a fourth dielectric layer extending between the second dielectric layer and the second semiconductive layer; and
a fifth dielectric layer within the second semiconductive layer.

9. The integrated assembly of claim 8, wherein:
the third dielectric layer is horizontally interposed between sidewalls of the layer stack and the second dielectric layer;
the second dielectric layer is horizontally interposed between the third dielectric layer and the fourth dielectric layer;
the fourth dielectric layer is horizontally interposed between the second dielectric layer and the second semiconductive layer; and
the second semiconductive layer is horizontally interposed between the fourth dielectric layer and the fifth dielectric layer.

10. The integrated assembly of claim 8, wherein:
the pillar structure further comprises a cavity that is defined by the fifth dielectric layer; and
the cavity extends into the first semiconductive layer and into the first dielectric layer.

11. The integrated assembly of claim 8, wherein the fifth dielectric layer corresponds to a cylindrical layer extending vertically within the pillar structure.

12. The integrated assembly of claim 8, wherein:
the third dielectric layer, the fourth dielectric layer, and the fifth dielectric layer comprise an oxide material;
the memory material comprises a nitride material; and
the second semiconductive layer comprises a polysilicon material.

13. An apparatus, comprising:
a common source layer;
a source-side select gate layer disposed over the common source layer, wherein a first dielectric layer extends vertically between the common source layer and the source-side select gate layer; and
a pillar comprising a string of memory cells and extending vertically through the source-side select gate layer and at least a portion of the common source layer,
wherein a first portion of the pillar that extends through the source-side select gate layer has a first diameter, and
wherein a second portion of the pillar that extends through the first dielectric layer has a second diameter that is larger than the first diameter.

14. The apparatus of claim 13, wherein:
the pillar comprises a first ledge between the first portion of the pillar and the second portion of the pillar, the first ledge being based at least in part on a difference between the first diameter and the second diameter; and
at least a portion of the source-side select gate layer contacts the first ledge.

15. The apparatus of claim 13, wherein a third portion of the pillar that extends through at least the portion of the common source layer has a third diameter that is larger than the second diameter.

16. The apparatus of claim 15, wherein:
the pillar comprises a second ledge between the second portion of the pillar and the third portion of the pillar, the second ledge being based at least in part on a difference between the second diameter and the third diameter; and
at least a portion of the first dielectric layer contacts the second ledge.

17. The apparatus of claim 13, further comprising:
a word line layer disposed over the source-side select gate layer, wherein the first portion of the pillar having the first diameter further extends through the word line layer.

18. The apparatus of claim 17, wherein a second dielectric layer extends vertically from the source-side select gate to the word line layer.

19. The apparatus of claim 13, wherein the pillar further comprises a channel.

20. A method, comprising:
forming a first dielectric layer over a first semiconductive layer and a plug structure formed in the first semiconductive layer;
forming a stack of second dielectric layers alternating with sacrificial layers;
forming a cavity that extends through the stack and the first dielectric layer to expose at least a portion of the plug structure;
recessing a portion of the first dielectric layer to form a ring-shaped void that is defined by a sidewall of the first dielectric layer, a bottom surface of the stack, and a top surface of the plug structure;
exhuming the plug structure to extend the cavity to comprise the ring-shaped void and to expose a surface of the first semiconductive layer; and
forming a pillar within the cavity, wherein the pillar comprises a cell stack.

21. The method of claim 20, wherein recessing the portion of the first dielectric layer comprises applying an etchant that is selective to the first dielectric layer relative to the second dielectric layers.

22. The method of claim 21, wherein:
the first dielectric layer comprises a carbon-doped nitride material and the second dielectric layers comprise a silicon oxide material; and
the etchant selectively etches the carbon-doped nitride material relative to the silicon oxide material.

23. The method of claim 21, wherein:
the first dielectric layer corresponds to a bilayer oxide layer that comprises a first oxide material and a second oxide material;
the second dielectric layers comprise the second oxide material; and
recessing the portion of the first dielectric layer comprises selectively etching the first oxide material relative to the second oxide material.

24. The method of claim 23, wherein:
forming the bilayer oxide layer comprises:
depositing the first oxide material using a first deposition technique, and
depositing the second oxide material using a second deposition technique that is different from the first deposition technique;
a first density of the first oxide material is lower than a second density of the second oxide material based at least in part on the first deposition technique and the second deposition technique being different; and
the etchant selectively etches the first oxide material relative to the second oxide material based at least in part on the first density of the first oxide material being lower than the second density of the second oxide material.

25. The method of claim 20, further comprising:
removing, after forming the pillar, the sacrificial layers to form a plurality of voids between the second dielectric layers; and
depositing a conductive material within the plurality of voids.
